(19) United States
(12) Patent Application Publication
(10) Pub. No.: US 2025/0317667 A1
(43) Pub. Date: Oct. 9, 2025

(54) Photon Detection Efficiency (PDE) modulation with multi-junction single-photon avalanche diode (SPAD) pixels

(71) Applicant: Apple Inc., Cupertino, CA (US)

(72) Inventors: Vyshakh Sanjeev, San Francisco, CA (US); Shingo Mandai, Mountain View, CA (US); Moshe Laifenfeld, Haifa (IL); Cristiano L. Niclass, San Jose, CA (US); Doron Shinbox, Tel Aviv (IL)

(21) Appl. No.: 19/017,663

(22) Filed: Jan. 12, 2025

Related U.S. Application Data
(60) Provisional application No. 63/575,739, filed on Apr. 7, 2024.

(51) Int. Cl. H04N 25/773; H04N 25/20

(52) U.S. Cl. CPC H04N 25/773; H04N 25/20

(57) ABSTRACT

A sensing device includes an array of sensing elements and a bias control circuit. Each sensing element of the array of sensing elements includes (i) a photosensitive material, which is configured to generate photoelectrons in response to incident optical radiation, and (ii) a plurality of avalanche diodes, which are disposed at different, respective locations within the sensing element in electrical communication with the photosensitive material and are configured, when reverse-biased, to generate electrical avalanches in response to the generated photoelectrons. The bias control circuit is configured to selectively set respective reverse-bias voltage levels of the avalanche diodes within each sensing element to different, respective values.

### CROSS-REFERENCE TO RELATED APPLICATIONS

This application claims the benefit of U.S.

Provisional Patent Application 63/575, 739, filed Apr. 16, 2024, whose disclosure is incorporated herein by reference.

### FIELD OF THE INVENTION

The present invention relates generally to optoelectronic devices, and particularly to high-sensitivity detector arrays.

### BACKGROUND

Single-photon avalanche diodes (SPADs), also known as Geiger-mode avalanche photodiodes (GAPDs), are sensing elements capable of capturing individual photons with very high time-of-arrival resolution, of the order of a few tens of picoseconds. They may be fabricated in dedicated semiconductor processes or in standard CMOS technologies. Arrays of SPAD sensing elements (also referred to as SPAD pixels), fabricated on a single chip, are used in 3D imaging cameras.

In a SPAD, a p-n junction is reverse-biased at a level well above the breakdown voltage of the junction. At this bias, the electric field is so high that a single charge carrier injected into the depletion layer, due to an incident photon, can trigger a self-sustaining avalanche. The leading edge of the avalanche current pulse marks the arrival time of the detected photon. The current continues until the avalanche is quenched by lowering the bias voltage down to or below the breakdown voltage. This latter function is performed by a quenching circuit, which may simply comprise a high-resistance ballast load in series with the SPAD, or may alternatively comprise active circuit elements.

SPAD arrays were previously reported in the patent literature. For example, U.S. Pat. No. 9,997,551 describes a sensing device including an array of sensing elements. Each sensing element includes a photodiode, including a p-n junction, and a local biasing circuit, coupled to reverse-bias the p-n junction at a bias voltage greater than a breakdown voltage of the p-n junction by a margin sufficient so that a single photon incident on the p-n junction triggers an avalanche pulse output from the sensing element. A bias control circuit is coupled to set the bias voltage in different ones of the sensing elements to different, respective values that are greater than the breakdown voltage.

### SUMMARY OF THE INVENTION

An embodiment of the present invention provides a sensing device including an array of sensing elements and a bias control circuit. Each sensing element of the array of sensing elements includes (i) a photosensitive material, which is configured to generate photoelectrons in response to incident optical radiation, and (ii) a plurality of avalanche diodes, which are disposed at different, respective locations within the sensing element in electrical communication with the photosensitive material and are configured, when reverse-biased, to generate electrical avalanches in response to the generated photoelectrons. The bias control circuit is configured to selectively set respective reverse-bias voltage levels of the avalanche diodes within each sensing element to different, respective values.

In some embodiments, the plurality of avalanche diodes includes a respective plurality of disjoint p-n junctions.

In some embodiments, the plurality of avalanche diodes includes a continuous p-n junction with multiple disjoint electrodes patterned to define the p-n junction.

In an embodiment, the bias control circuit is configured to selectively set the respective reverse-bias voltage levels so that at least one of the avalanche photodiodes in a given sensing element is set to a reverse-bias voltage level greater than a breakdown voltage of the avalanche diodes and another of the avalanche diodes in the given sensing element is set to a reverse-bias voltage lower than the breakdown voltage of the avalanche diodes.

In another embodiment, the bias control circuit is configured to set the reverse-bias voltage lower than the breakdown voltage of the avalanche diodes by electrically grounding the avalanche diodes.

In some embodiments, each sensing element includes a switching circuit, which is configured to apply the same reverse-bias voltage level to a group of the avalanche diodes in the sensing element.

In some embodiments, the avalanche diodes in each sensing cell include a central photodiode surrounded by a plurality of peripheral photodiodes.

In an embodiment, each sensing element includes a switching circuit comprising multiple inverters coupled to respective sets of one or more of the avalanche diodes and an OR gate coupled to merge respective outputs of the multiple amplifiers.

In some embodiments, the plurality of diodes give rise to a total effective active area of each sensing element, and wherein by selectively setting respective reverse-bias voltage levels, the control circuit is configured to change the total effective active area.

In some embodiments, each sensing element comprises a switching circuit comprising multiple inverters coupled to respective sets of one or more of the avalanche diodes, respective one-shot circuits coupled to the inverters, and an OR gate coupled to merge respective outputs of the multiple one-shot circuits.

In an embodiment, each diode of the plurality of diodes is coupled to a respective switching circuit and a readout circuitry comprising an inverter.

In some embodiments, each diode of the plurality of diodes is coupled to a respective switching circuit and a readout circuitry comprising an inverter.

In an embodiment, the photosensitive material is configured to generate the photoelectrons in response to near infrared (NIR) optical radiation.

In another embodiment, the photosensitive material comprises silicon.

In an embodiment, the photosensitive material is configured to generate the photoelectrons in response to short wave infrared (SWIR) radiation.

In another embodiment, the photosensitive material includes germanium.

There is further provided, in accordance with another embodiment of the present invention, a sensing method, including, in an array of sensing elements, in each sensing element of the array, generating photoelectrons in response to incident optical radiation using a photosensitive material. Electrical avalanches are generated in response to the generated photoelectrons using a plurality of avalanche diodes, when reverse-biased, which are disposed at different, respective locations within the sensing element in electrical communication with the photosensitive material and are configured. Using a bias control circuit, respective reverse-bias voltage levels of the avalanche diodes are selectively set within each sensing element to different respective values.

The present invention will be more fully understood from the following detailed description of the embodiments thereof, taken together with the drawings in which:

### BRIEF DESCRIPTION OF THE DRAWINGS

FIG. 1 is a block diagram that schematically illustrates a SPAD-based sensing device, in accordance with an embodiment of the invention;

FIGS. 2A and 2B are schematic vertical and lateral sectional views of a sensing element, in accordance with an embodiment of the invention;

FIG. 2C is a lateral sectional view of a sensing element, in accordance with another embodiment of the invention;

FIGS. 3A, 3B, 3C, 3D, 3E, and 3F are electrical circuit diagrams that schematically illustrate components of a sensing element, in accordance with six different embodiments of the invention; and

FIG. 4 is a schematic vertical sectional view of a sensing element, in accordance with another embodiment of the invention.

### DETAILED DESCRIPTION OF EMBODIMENTS

In sensing elements of SPAD array (also referred to herein as “SPAD pixels” or “avalanche photodiodes”), higher pixel sensitivity, also called hereinafter “increased photon detection efficiency (PDE),” is typically desired for enhanced system performance, such as higher signal-to-noise ratio, SNR (since SNR∝\sqrt{PDE}).

However, due to the dead time of SPAD pixels following an avalanche event, higher sensitivity is not desirable under all illumination conditions, e.g., due to pixel saturation. For example, in scenes with strong background illumination, improved system performance may be achieved in some circumstances by lowering pixel sensitivity. In particular, range-finding of short-range targets in high-ambient light scenes may benefit from low pixel sensitivity.

One possible way to lower sensitivity is to adjust (e.g., modulate) the potential difference across the SPAD and therefore adjust the excess bias (i.e., bias past the breakdown voltage of the SPAD). The drawback of such an approach is degradation in SPAD timing performance due to timing performance (e.g., dead time) dependence on the excess bias. The range of sensitivity modulation is also limited with such an implementation in practice (i.e., does not cover the range that makes the benefit of modulation realizable).

Embodiments of the present invention that are described herein provide SPAD pixels and readout circuitries that enable the adjustment of individual pixel sensitivity (e.g., adjusting the probability that an incident photon will cause an avalanche pulse). In the disclosed embodiments, a sensing device comprises an array of pixels, each comprising each a plurality of avalanche diodes. Every pixel comprises (a) a photosensitive material, which generates photoelectrons in response to incident optical radiation, and (b) a plurality of avalanche diodes at different, respective locations within the sensing element in electrical communication with the photosensitive material. A bias control circuit selectively sets respective reverse-bias voltage levels of the avalanche diodes within each sensing element to different, respective values.

In one example, the bias control circuit controls switching circuits that can enable/disable one or more of the pixel's diodes by switching on or off a reverse bias of each of the diodes.

When reverse-biased with sufficient voltage, the diodes in each pixel generate electrical avalanches in response to the generated photoelectrons. The bias control circuit can change each pixel's sensitivity by changing the fraction of enabled diodes in the pixels. In another interpretation, the control circuit changes each pixel's sensitivity by changing the effective active area of each pixel, which changes the probability of an incident photon causing an avalanche pulse in the pixel.

In one embodiment, the plurality of the avalanche diodes of each pixel is realized by patterning a respective plurality of p-n junctions in one of the active layers of the pixel (e.g., the n-type layer) to divide it into disjoint regions (e.g., disjoint p-n junctions) and electrically contacting each region separately. In another embodiment, the entire pixel comprises a continuous p-n junction with multiple electrodes patterned to it to effectively create the disjoint avalanche diodes.

In one embodiment, the bias control circuit can set the reverse bias voltage level individually in each of the diodes in any given pixel. In other embodiments, a portion of the diodes are grouped together such that one switching circuit applies the same bias level to the entire portion.

The bias control circuit sets the bias voltage to a level greater than the breakdown voltage of the p-n junction in order to enable the junction. When the bias voltage is set lower than the breakdown voltage of the p-n junction, the junction is disabled. In one example, the switching circuit disables the photodiode by grounding the junction (zeroing the reverse bias).

In some embodiments, a global bias generator applies a global bias voltage to all of the sensing elements in the array. The bias control circuit sets the switching circuits of the individual diodes in each pixel (e.g., according to different regions over the array) to switch the reverse bias on and off to each of the diodes. Each individual diode and its switching circuits define a sub-pixel.

To determine in real-time the required level of sensitivity, the pixel can be operated at a low sensitivity during a portion of an acquisition time window (e.g., over a fraction of the acquisition sub-frames of a total number of sub-frames used during a given acquisition period). A processor can command the bias control circuit to increase the sensitivity based on the low-sensitivity information (e.g., ambient light level). In another example, the sensitivity control algorithm divides the sub-frames into groups, and, in each group of sub-frames, the system is sensitivity-configured differently for a different use case (a short target distance or a longer-range mode, etc.)

Another way to optimize real-time sensitivity selection, which may require on-chip processing, is to apply dynamic feedback from one sub-frame to the next. Once the sensor detects that the count rate (SPAD firing rate) is larger than a given set threshold, it reduces the pixel sensitivity.

The disclosed technique of adjusting PDE can be useful in optimizing the detection capabilities of the array, for example, by tailoring the sensitive region of the array to the shape of an illuminating light beam, or of an area of interest in a scene being imaged. Using the disclosed technique, a processor can vary sensitivity among the sensing elements in the array by setting the PDE of the sensing elements. For example, PDE can be set lower in a certain region of the array than outside the region. In general, any region, of any suitable shape, may be chosen in this fashion. In some embodiments, the bias control circuit can modify the sensitivity of individual sensing elements dynamically to sweep the selected region across the array.

Some embodiments provide readout circuitries that leverage the disclosed multi-SPAD readout approaches. In one example, a one-shot circuit is added to each sub-pixel output to reduce the output pulse width. This way, using an OR gate, even when one of the sub-pixels in the pixel fires, the other sub-pixels are available. By reducing the pulse widths in this manner, we can reduce dead time following the firing of each SPAD and improve the dynamic range of the pixel.

The strategies devised above can be used to adjust PDE in different wavelength bands, e.g., for near infrared (NIR, for example in the range of 750-1400 nm) or for short-wave infrared (SWIR, for example in the range of 1400-3000 nm). Different types of detectors, using photon conversion materials (photosensitive materials) with different bandgap energies, can be used to fit different wavelength bands.

The disclosed embodiments allow control over pixel sensitivity to simultaneously support multiple features, such as macro-mode autofocus (short range) and tele-autofocus (far range) with the same pixel array. The principles of the present invention can be applied, for example, in SPAD imaging arrays, such as those used in 3D cameras based on time-of-flight (TOF) measurement, as well as in silicon photomultiplier (SiPM) devices and other sorts of avalanche diode arrays.

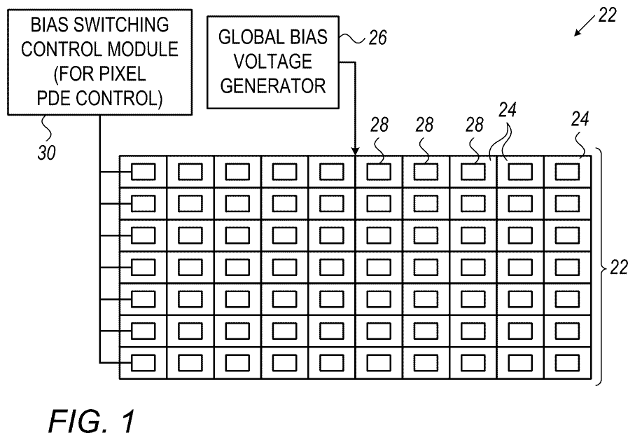

FIG. 1 is a block diagram that schematically illustrates a sensing device 20, in accordance with an embodiment of the invention. Device 20 comprises an array 22 of sensing elements 24 (also referred to as pixels), each comprising a SPAD and associated bias switching circuits 28, controlled by a bias control circuit 30, configured as a bias switching control module, as described further hereinbelow. A global high-voltage bias generator 26 applies a global bias voltage to all of the sensing elements 24 in array 22. The local bias switching circuits 28 in each sensing element 24 enable or disable the bias, and hence the respective p-n junctions inside the pixel.

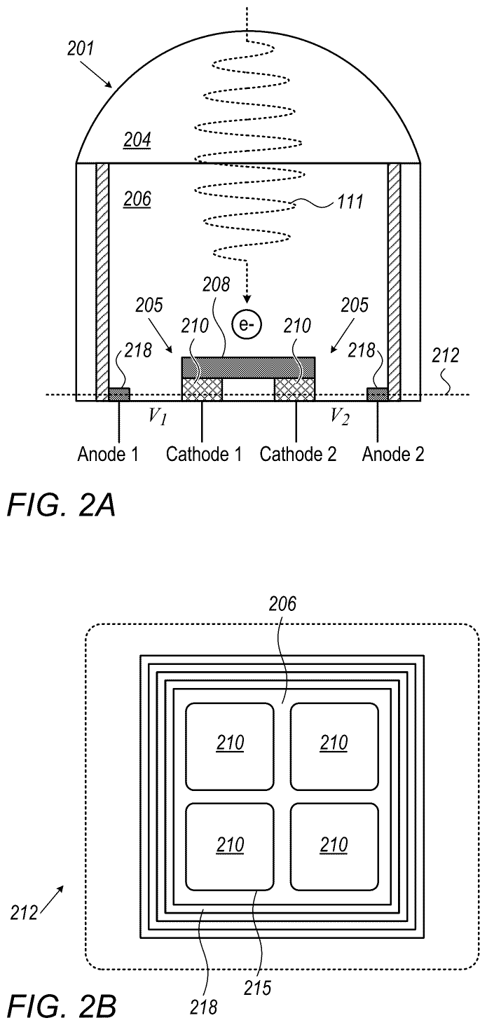

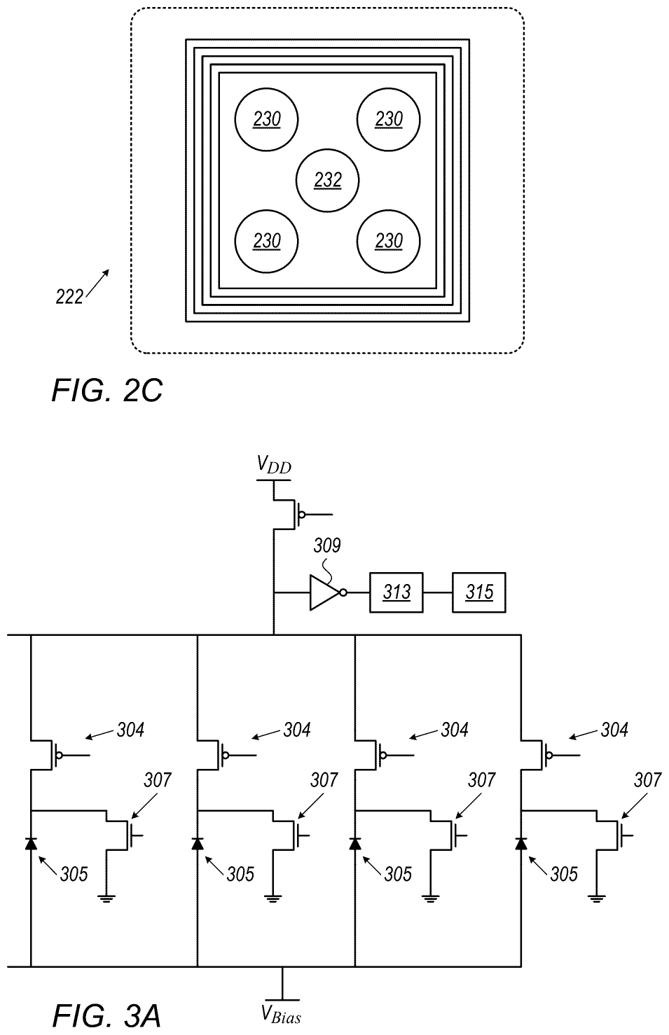

FIGS. 2A and 2B are schematic vertical and lateral sectional views 201 and 212, respectively of a sensing element 24, in accordance with an embodiment of the invention.

The vertical sectional view of FIG. 2A shows two disjoint diodes 205, each made of a p-type semiconductor layer 208, and disjoint n-type semiconductor layers 210. Layer 208 is in ohmic contact with anodes 1 and 2 via a contact semiconductor layer 218. Layers 210 are each in ohmic contact with respective cathodes 1 and 2. Separate bias voltages V₁ and V₂ are applied to disjoint diodes 205 to enable an avalanche current spike to be generated in response to a photoelectron in each of diodes 205.

In vertical sectional view 201, a microlens 204 focuses an incident near IR (NIR) photon 111 into a photosensitive material 206, in this example a silicon volume, which converts the photon into an electron. The bias voltage Vᵢ on at least one of the p-n junctions of diodes 205, which are in electrical communication with the photosensitive material, causes the electron to initiate a spike of breakdown current, referred to as an avalanche, giving rise to an output signal. If a voltage Vᵢ is not applied on the p-n junction of a diode 205, an effective area 215 (seen in FIG. 2B) of its layer 210 does not contribute to pixel sensitivity, thereby lowering total sensitivity.

Lateral sectional view 212 of FIG. 2B shows four disjoint diodes 205 realized by etching the n-type semiconductor layer 210. The n-type layer in each diode 205 defines an active area 215.

By activating or deactivating each of the diodes 205 of the pixel, the sensitivity of pixel 210 can be adjusted from zero to maximal values in steps of 25%.

FIG. 2C is a lateral sectional view of a sensing element 222, in accordance with another embodiment of the invention. In this layout, a central diode 232 is surrounded by a plurality (four in the example) of peripheral diodes 230. The active (avalanche) areas of the diodes are defined by the localized high electric field regions at the interface between the p-type and n-type semiconductor layers. A benefit of such an arrangement is reducing the granularity in sensitivity modulation, enabling control of sensitivity in smaller steps.

A particular possible advantage of an N=5 layout over an N=4 layout is a boosted sensitivity by using the central junction. Higher maximum pixel sensitivity can be explained by either having a more optimal arrangement against the microlens and/or by the increased total useful area of the pixel as the number of disjoint junctions, N, increases. However, increasing N may require tighter semiconductor processing control per given pixel size.

Other layouts of disjoint diodes can be implemented, mutatis mutandis, to adjust pixel PDE characteristics. These layouts can have different diode shapes and arrangements, limited only by feasible circuit design and CMOS process limitations.

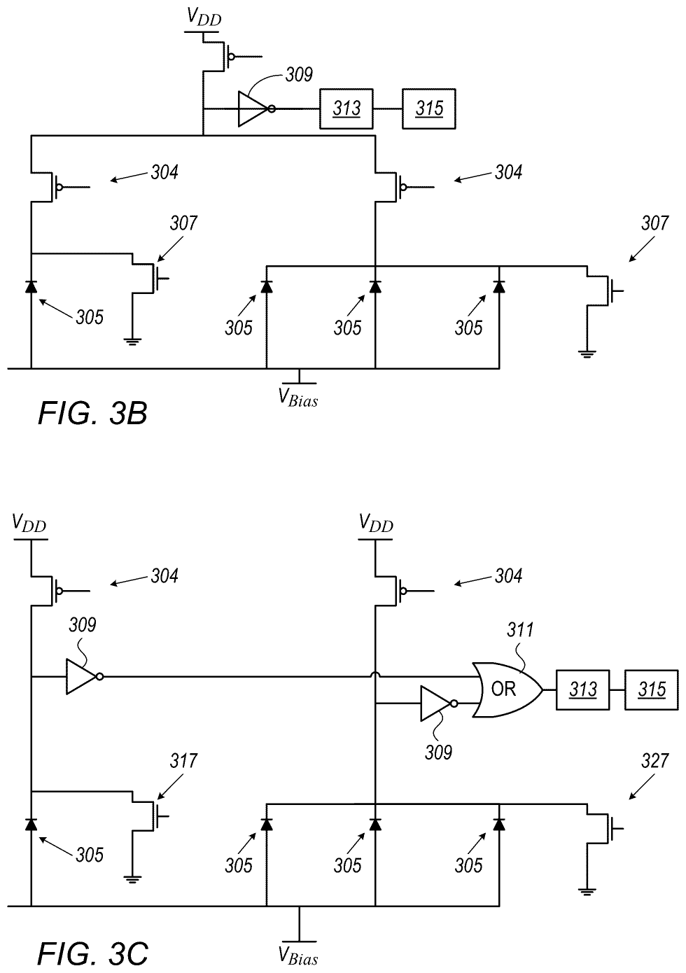

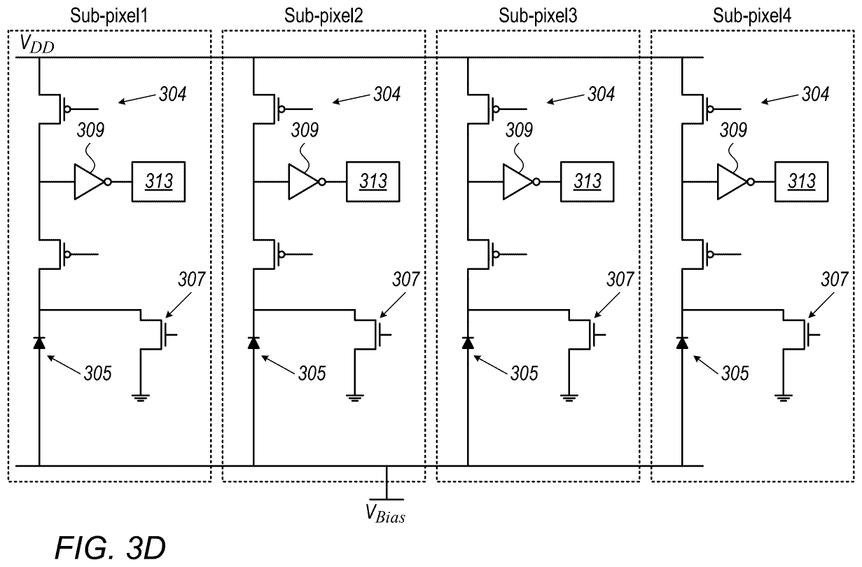

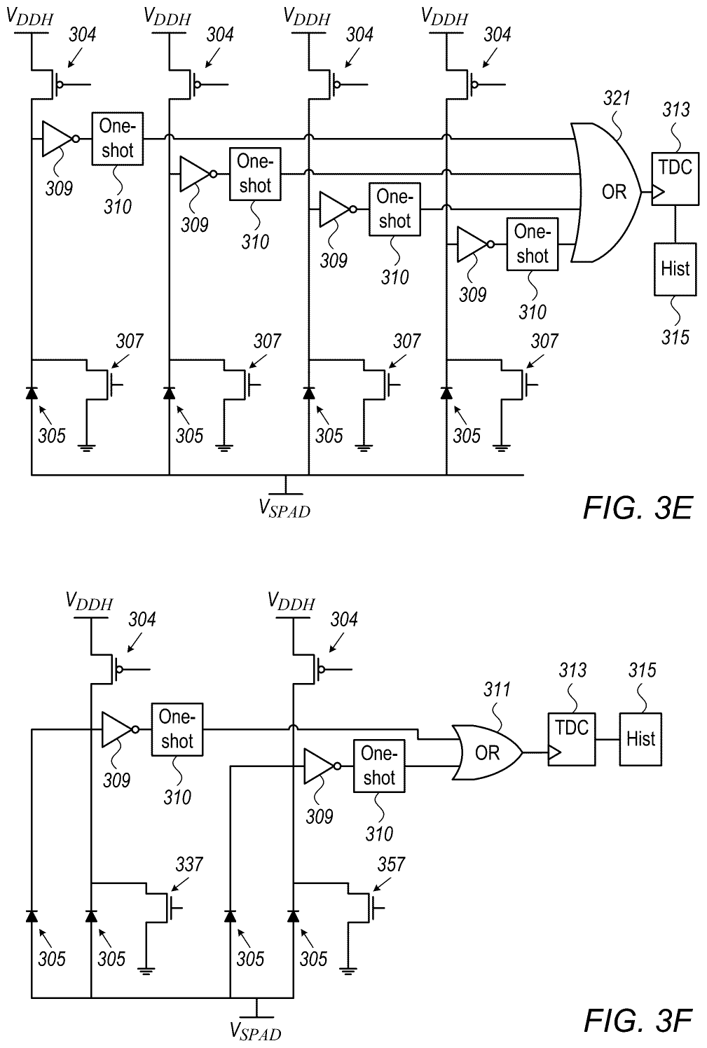

FIGS. 3A, 3B, 3C, 3D, 3E, and 3F are electrical circuit diagrams that schematically illustrate components of a sensing element, in accordance with six different embodiments of the invention. In all of the embodiments of FIGS. 3A-C, diodes 305 and respective quenching circuits 304 are coupled together in series. The global bias voltage V_{bias} is applied to all sensing elements 305 by global bias generator 26.

FIG. 3A shows an electrical circuit that can be used with the pixel illustrated in FIGS. 2A and 2B. Local bias switching circuit 28 (seen in FIG. 1) in each sensing element comprises switches 307 and enables or disables the bias of each diode 305 by turning respective switches 307 on and off. In the pictured example, turning off any switch 307 grounds the respective individual diode 305, thereby deactivating it.

Sensitivity is varied between zero and a maximum in four steps, depending on the fraction of activated diodes 305. In response to each photon captured by the activated portion of the pixel, an avalanche pulse is outputted via a readout circuitry comprising an inverter 309 (e.g., an inverting amplifier), which outputs the signal into a time-to-digital converter (TDC) 313. The digital signal is then input to a histogram readout circuitry 315 to estimate the time of flight of the incident photon 111. Dedicated low- and high-sensitivity modes of operation can be used if the area is limited. Such a PDE adjustment circuit configuration can reduce the number of transistors. For example, FIG. 3B shows an alternative electrical circuit in which three of the four diodes are grouped under one switching element 307. The other diode 305 can be switched independently. The arrangement of FIG. 3B yields pixel PDE control at levels of 0% (when pixel is to be disabled), 25%, 75%, and 100%.

FIG. 3C shows a pixel PDE control layout with improved timing performance compared to a single-amplifier architecture. In this embodiment, PDE sensitivity levels identical to FIG. 3B can be achieved, with the readout circuitry comprising two inverters 309, with their outputs merged via an OR gate 311. The signal is output into a TDC 313. The digital signal is then input to a histogram readout circuitry 315 to estimate the time of flight of the incident photon 111. With OR gate layout, if the 75% level is not operational (e.g., due to saturation), the OR gate can pass a signal from the lower-level sensitivity of 25%, and vice versa if the sensor benefits from this configuration for the given scene.

The layout of FIG. 3C includes switches 317 and 327 to enable a 25% sensitivity mode (e.g., with switch 317 open and switch 327 grounded) or a 100% sensitivity mode with both switches open. A 0% sensitivity, which is sometimes required, is achieved when all junction cathode nodes are grounded by both switches 317 and 327.

FIG. 3D shows an electrical circuit with individual SPAD readout, where each diode 305 (e.g., of a sub-pixel of the SPAD pixel) has its own readout circuitry comprising quenching circuit 304, switching element 307, and inverter 309. The signals are output into individual TDCs 313. Using dedicated readout circuitry per each diode 305 can further increase specificity, e.g., spatial resolution characteristics and temporal response characteristics of the sensing element.

FIG. 3E shows an electrical circuit with individual SPAD readout, where each diode 305 (e.g., of a sub-pixel of the SPAD pixel) has its own readout circuitry comprising quenching circuit 304, switching element 307, and inverter 309. A one-shot circuit (a monostable multivibrator 310) is added to the pixel output to reduce the output pulse width. The outputs of multivibrators 310 are merged via an OR gate 321. This way, even when one of the four junctions in the pixel fires, the other junctions are available. By reducing the pulse widths output by multivibrators 310, the dynamic range is improved, and SNR is larger across the range of distances to the light source.

FIG. 3F shows a pixel PDE control layout with improved timing performance compared to a single-amplifier architecture and improved photosensitive fill factor compared to the embodiment of FIG. 3E. In this embodiment, the readout circuitry comprises two inverters 309, each shared by a pair of diodes 305, as well as shared quenching circuits 304. A one-shot circuit (monostable multivibrator 310) is added to the pixel output to reduce the output pulse width, with the pulse outputs merged via OR gate 311. The signal is output to TDC 313. The digital signal is then input to histogram readout circuitry 315 to estimate the time of flight of the incident photons.

The layout of FIG. 3F includes switches 337 and 357 to enable the 25% and 50% sensitivity modes or a 100% sensitivity mode with both switches open. The 25% sensitivity is achieved when all junction cathode nodes are grounded by both switches 337 and 357. The use of OR gate 311 in combination with switches 337 and 357 allows the sensitivity and saturation of the pixel to be adapted for a wide range of lighting conditions and applications.

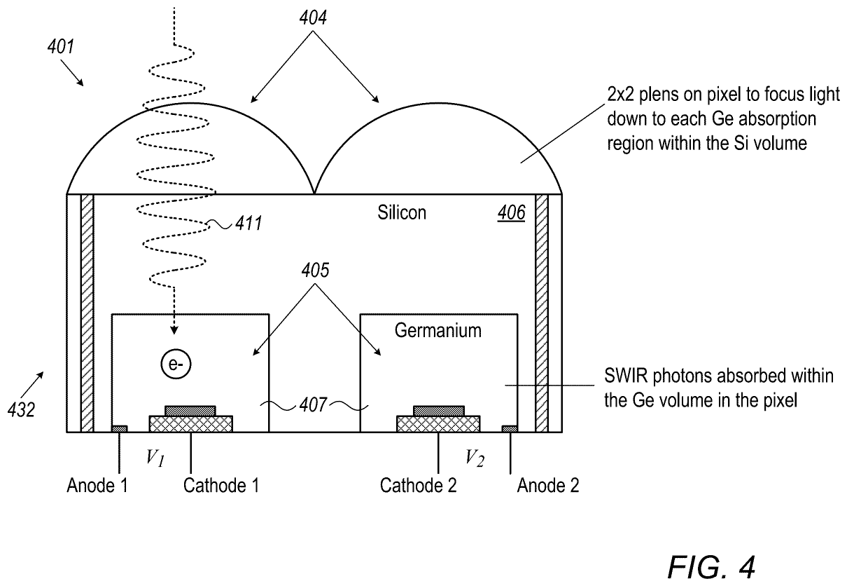

The strategies devised above can be used to adjust PDE for various types of detectors, e.g., using photosensitive materials with different bandgap energies to fit different wavelength bands without sacrificing the maximum nominal PDE offered by the device. For example, FIG. 4 is a schematic vertical cross section 432 of a SPAD pixel 401 having a 2×2 array of disjoint diodes 405, in accordance with another embodiment of the invention. Each microlens 404 can focus an incident SWIR photon 411 into a respective germanium volume 407 (seen embedded in silicon volume 406), wherein the photosensitive germanium converts the SWIR photon into a photoelectron. The bias voltage Vⱼ on the respective p-n junction 405, when applied, causes the electron to initiate a spike of respective breakdown current that gives rise to a detectable output signal pulse.

By activating or deactivating each of the diodes 405 of the pixel, the sensitivity of pixel 401 can be adjusted from zero (called herein 0%) to one maximal (called herein 100%) in steps of 25%.

It will be appreciated that the embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. A sensing device, comprising:
an array of sensing elements, each sensing element comprising:
a photosensitive material, which is configured to generate photoelectrons in response to incident optical radiation; and
a plurality of avalanche diodes, which are disposed at different, respective locations within the sensing element in electrical communication with the photosensitive material and configured, when reverse-biased, to generate electrical avalanches in response to the generated photoelectrons; and
a bias control circuit, which is configured to selectively set respective reverse-bias voltage levels of the avalanche diodes within each sensing element to different, respective values.

2. The device according to claim 1, wherein the plurality of avalanche diodes comprises a respective plurality of disjoint p-n junctions.

3. The device according to claim 1, wherein the plurality of avalanche diodes comprises a continuous p-n junction with multiple disjoint electrodes patterned to define the p-n junction.

4. The device according to claim 1, wherein the bias control circuit is configured to selectively set the respective reverse-bias voltage levels so that at least one of the avalanche photodiodes in a given sensing element is set to a reverse-bias voltage level greater than a breakdown voltage of the avalanche diodes and another of the avalanche diodes in the given sensing element is set to a reverse-bias voltage lower than the breakdown voltage of the avalanche diodes.

5. The device according to claim 4, wherein the bias control circuit is configured to set the reverse-bias voltage lower than the breakdown voltage of the avalanche diodes by electrically grounding the avalanche diodes.

6. The device according to claim 1, wherein each sensing element comprises a switching circuit, which is configured to apply the same reverse-bias voltage level to a group of the avalanche diodes in the sensing element.

7. The device according to claim 1, wherein the avalanche diodes in each sensing cell comprise a central photodiode surrounded by a plurality of peripheral photodiodes.

8. The device according to claim 1, wherein each sensing element comprises a switching circuit comprising multiple inverters coupled to respective sets of one or more of the avalanche diodes and an OR gate coupled to merge respective outputs of the multiple inverters.

9. The device according to claim 1, wherein each sensing element comprises a switching circuit comprising multiple inverters coupled to respective sets of one or more of the avalanche diodes, respective one-shot circuits coupled to the inverters, and an OR gate coupled to merge respective outputs of the one-shot circuits.

10. The device according to claim 1, wherein the plurality of diodes give rise to a total effective active area of each sensing element, and wherein by selectively setting respective reverse-bias voltage levels, the control circuit is configured to change the total effective active area.

11. The device according to claim 1, wherein each diode of the plurality of diodes is coupled to a respective switching circuit and a readout circuitry comprising an inverter.

12. The device according to claim 1, wherein the photosensitive material is configured to generate the photoelectrons in response to near infrared (NIR) optical radiation.

13. The device according to claim 12, wherein the photosensitive material comprises silicon.

14. The device according claim 1, wherein the photosensitive material is configured to generate the photoelectrons in response to short wave infrared (SWIR) radiation.

15. The device according to claim 13, wherein the photosensitive material comprises germanium.

16. A sensing method, comprising:
in an array of sensing elements, in each sensing element of the array:
generating photoelectrons in response to incident optical radiation using a photosensitive material; and
generating electrical avalanches in response to the generated photoelectrons using a plurality of avalanche diodes, when reverse-biased, which are disposed at different, respective locations within the sensing element in electrical communication with the photosensitive material and are configured; and
selectively setting respective reverse-bias voltage levels of the avalanche diodes within each sensing element to different, respective values.

17. The sensing method according to claim 16, wherein the plurality of avalanche diodes comprises a respective plurality of disjoint p-n junctions.

18. The sensing method according to claim 16, wherein selectively setting the respective reverse-bias voltage levels comprises setting at least one of the avalanche photodiodes in a given sensing element to a reverse-bias voltage level greater than a breakdown voltage of the avalanche diodes and setting another of the avalanche diodes in the given sensing element to a reverse-bias voltage lower than the breakdown voltage of the avalanche diodes.

19. The sensing method according to claim 16, wherein selectively setting the respective reverse-bias voltage levels comprises applying the same reverse-bias voltage level to a group of the avalanche diodes in the sensing element.

20. The sensing method according to claim 16, wherein each sensing element comprises a switching circuit comprising multiple inverters coupled to respective sets of one or more of the avalanche diodes, respective one-shot circuits coupled to the inverters, and an OR gate coupled to merge respective outputs of the multiple one-shot circuits.
